(19) United States
(12) Patent Application Publication
(10) Pub. No.: US 2026/0136502 A1
(43) Pub. Date: May 14, 2026

(54) COVER FOR A SIGNAL CONNECTOR

(71) Applicant: Telefonaktiebolaget LM Ericsson (publ), Stockholm (SE)

(72) Inventors: Claudio D'INCÀ, Genova (IT); Sergio MOSTI, Genova (IT)

(73) Assignee: Telefonaktiebolaget LM Ericsson (publ), Stockholm (SE)

(21) Appl. No.: 19/120,478

(22) PCT Filed: Oct. 13, 2023
(86) PCT No.: PCT/EP2023/078572

§ 371 Date: Apr. 11, 2025

Related U.S. Application Data
(60) Provisional application No. 63/416,199, filed on Oct. 14, 2022.

(51) Int. Cl. H05K 7/20; H01R 13/631

(52) U.S. Cl. CPC H05K 7/2039; H01R 13/631

(57) ABSTRACT

A cover for a cage is provided. The cage is configured to guide a signal connector towards an interface for connection with the signal connector. The cover is attachable to a first surface of the cage for thermally coupling the signal connector received within the cage to a heat sink disposed outside the cage. The cover comprises an interface portion engageable with the first surface of the cage; an opening formed in the interface portion; and one or more thermal coupling members resiliently connected to the interface portion and extending at least partially across the opening, wherein a first portion of one or more of the thermal coupling members is disposed on a first side of the interface portion and a second portion of one or more of the thermal coupling members is disposed on a second side of the interface portion opposite the first side.

### TECHNICAL FIELD

The present disclosure relates to a cover for a signal connector. In some aspects, the cover provides for improved thermal management properties.

### BACKGROUND

In Radio Access nodes, optical transceivers are becoming more power demanding, for example, in order to provide for an increase of the bitrate and additional requested functions. Especially in very dense optical units, a special care must be taken to manage the thermal design for heat dissipation in order to provide the requested node capacity bandwidth, in terms of number of transceivers located on the front face with respect to the unit space occupation inside a rack.

Currently, 10 G Small Form Factor Pluggable (SFP) Dense Wavelength Division Multiplexer (DWDM) transceivers show a power consumption of 1.5 W. A current solution at 10 G for a Fronthaul telecoms equipment located in one rack unit (44.45 mm thickness) is able to thermally manage the maximum possible number of front optical transceivers. A next generation DWDM SFP28 may show a power consumption of 2.5 W, and the power consumption could increase further if the SFP28 includes a full tuneable laser or other functions, such as wavelength auto-negotiation. At the same time, it is desirable for the rack space available, such as 1 rack unit (1 RU) in a “pizza box” format, to be able to host the maximum number of front interfaces (e.g. more than 42), in order to optimize space occupied inside the rack. It is useful to utilize the full space available on the front of the unit to place a maximum number of optical transceivers. In order to manage components with high heat outputs, a new and efficient way of thermal management would be advantageous.

One issue that has arisen in the development of such connector systems is the build up of heat in and around the connector. This problem is particularly pronounced for active cable assemblies (i.e., connectors or cables having embedded circuitry to boost their performance or carry out additional functions). To address this problem, heat sinks have been used to dissipate the heat that builds up in the connector.

### SUMMARY

According to an aspect of the present disclosure, there is provided a cover for a cage, the cage configured to guide a signal connector towards an interface for connection with the signal connector. The cover is attachable to a first surface of the cage for thermally coupling the signal connector received within the cage to a heat sink disposed outside the cage. The cover comprises: an interface portion engageable with the first surface of the cage; an opening formed in the interface portion; and one or more thermal coupling members resiliently connected to the interface portion and extending at least partially across the opening. A first portion of one or more of the thermal coupling members is disposed on a first side of the interface portion and a second portion of one or more of the thermal coupling members is disposed on a second side of the interface portion opposite the first side.

The second portion of the one or more thermal coupling members may thereby be configured to engage a signal connector received within a cage to which to the cover is attached.

The cage may be a Small Form factor Pluggable (SFP) cage, e.g. for receiving an SFP module/connector, such as a SFP optical transceiver module.

The thermal coupling members may comprise a corrugated plate comprising a plurality of alternating ridges and valleys that alternatingly extend through the opening between the first and second sides of the interface portion. The first portion may comprise the one or more ridges of the corrugated plate and the second portion may comprise the one or more valleys of the corrugated plate.

The cover may further comprise a thermal pad at least partially enclosed between the first and second portions of the thermal coupling members. The thermal coupling members may be resiliently deformable relative to one another in order to compress the thermal pad between the first and second portions.

The cover may further comprise one or more side interface portions for engaging one or more side surfaces of the cage. The side interface portions may be arranged at angles, e.g. perpendicular, relative to the interface portion.

The cover may further comprise one or more side openings formed in the one or more side interface portions; and one or more side thermal coupling members resiliently connected to respective ones of the one or more side interface portions and extending at least partially across one or more of the side openings formed in the respective side interface portion. A first portion of one or more of the side thermal coupling members may be disposed on a first side of the respective side interface portion and a second portion of one or more of the side thermal coupling members may be disposed on a second side of the respective side interface portion. The second portion of the one or more of side thermal coupling members may thereby be configured to engage a side of the signal connector, when the signal connector is received within the cage.

The cover may further comprise a side thermal pad corresponding to each of the side thermal coupling members, The side thermal pads may be at least partially enclosed between the first and second portions of each of the side thermal coupling members.

The cage may be a multiple slot cage configured to receive a plurality of the signal connectors side-by-side with one another within respective slots of the cage. The interface portion may comprise a plurality of the openings formed in the interface portion arranged to be at least partially aligned with two or more slots of the cage, e.g. respectively, for example, when the cover is attached to the multiple slot cage. The cover may further comprise a plurality of the thermal coupling members resiliently connected to the interface portion and extending at least partially across respective ones of the openings. A first portion of the thermal coupling members may be disposed on a first side of the interface portion and a second portion of the thermal coupling members may be disposed on a second side of the interface portion opposite the first side.

According to another aspect of the present disclosure, there is provided a cage assembly comprising: a cage configured to guide a signal connector towards an interface for connection with the signal connector, wherein the cage comprises a first surface; and the above-mentioned cover for the cage, wherein the interface portion of the cover is engaged with the first side of the cage.

The cage may comprise an aperture formed in the first surface. The second portions of the one or more thermal coupling members may extend through the aperture into an interior space of the cage.

The assembly may further comprise a heatsink, wherein the heatsink comprises a heatsink surface spaced apart from the first side of the cage on an opposite side of the interface portion from the cage. The thermal coupling members may be configured such that insertion of the signal connector into the cage urges, e.g. resiliently deforms, the thermal coupling members towards the heatsink surface. The thermal coupling members may be configured such that, when the signal connector is received within the cage, the first portions of the thermal coupling member contact the heat sink surface. The thermal coupling members may be configured such that, when the signal connector is received within the cage, the thermal coupling members are compressed between the cage and/or the signal connector, and the heatsink.

The cage may be configured to guide the signal connector along a longitudinal direction when the signal connector is inserted into the cage. The plurality of ridges and valleys of the corrugated thermal coupling member may extend in a transverse direction that is perpendicular to the longitudinal direction.

The cage may further comprise a pair of opposing side surfaces arranged on either lateral side of the first surface; and one or more side apertures formed in the side surfaces. The second portions of the one or more side thermal coupling members may extend through the side apertures into the interior space of the cage.

The assembly may further comprise a further cage configured to guide a further signal connector towards an interface for connection with the further signal connector. The further cage may comprise a first surface. The further cage may further comprise a pair of opposing side surfaces arranged on either lateral side of the first surface, and one or more side apertures formed in the side surfaces. The further cage may be arranged such that one of the side surfaces of the further cage is spaced apart from one of the side surfaces of the cage. The assembly may further comprise a further of the above-mentioned covers, wherein the interface portion of the further cover is engaged with the first side of the further cage. The second portions of the one or more side thermal coupling members of the further cover may extend through the side apertures of the further cover into an interior space of the further cage. The heatsink may comprise a projecting portion projecting from the heatsink surface between the cage and the further cage. The first portions of the side thermal coupling members of the cover and further cover may engage the projecting portion of the heat sink, e.g. when the signal connector and the further signal connector are installed in the cage and further cage respectively.

The projecting portion may comprise a taper surface at a distal end of the projecting portion configured to urge the side thermal coupling members of the cage and further cage away from the projecting portion as the projecting portion is assembled between the cage and the further cage.

The cage may be a multiple slot cage configured to receive a plurality of the signal connectors side-by-side with one another within respective slots of the cage. The first surface of the cage and the interface portion of the cover may extend across each of the slots for signal connector provided in the cage.

To avoid unnecessary duplication of effort and repetition of text in the specification, certain features are described in relation to only one or several aspects or embodiments of the invention. However, it is to be understood that, where it is technically possible, features described in relation to any aspect or embodiment of the invention may also be used with any other aspect or embodiment of the invention. For example, features described in relation to the first mentioned aspect may be combined with the features of the second mentioned aspect.

### BRIEF DESCRIPTION OF THE DRAWINGS

For a better understanding of the present invention, and to show more clearly how it may be carried into effect, reference will now be made, by way of example, to the accompanying drawings, in which:

FIG. 1A is a partial perspective view of a conventional interface module;

FIG. 1B is a perspective sectional view of a main unit comprising a conventional interface module;

FIG. 2 a schematic sectional view of a conventional arrangement of an interface module, a PCB and a heat sink;

FIG. 3A is a perspective view of a conventional Small Form factor Pluggable (SFP) cage having an aperture in one or more surfaces of the cage;

FIG. 3B is a perspective view of another conventional SFP cage having enclosed sides;

FIG. 4A is a perspective top view of a cover for an SFP cage according to arrangements of the present disclosure;

FIG. 4B is a perspective bottom view of the cover shown in FIG. 4A;

FIG. 4C is a side sectional view of the cover shown in FIGS. 4A and 4B;

FIG. 5A is a top perspective view of an assembly comprising the cover shown in FIGS. 4A to 4C coupled to the SFP cage shown in FIG. 3A;

FIG. 5B is a top perspective view of an assembly comprising the cover shown in FIGS. 4A to 4C coupled to the SFP cage shown in FIG. 3B;

FIG. 6A is a perspective view of a cage assembly according to arrangements of the present disclosure;

FIG. 6B is a side view of the cage assembly shown in FIG. 12A;

FIG. 6C is a perspective view another cage assembly according to arrangements of the present disclosure;

FIG. 7A is a side perspective view of an SFP cage according to arrangements of the pressure disclosure, showing a first side of the SFP cage;

FIG. 7B is a side perspective view of the SFP cage shown in FIG. 8A, showing a second side of the SFP cage;

FIG. 8A is a side perspective view showing the first side of an assembly comprising the SFP cage shown in FIGS. 7A and 7B and the cover shown in FIGS. 4A to 4C;

FIG. 8B is a side perspective view showing the second side of the assembly shown in FIG. 8A;

FIG. 9A is a perspective top view of another cover for an SFP cage according to arrangements of the present disclosure;

FIG. 9B is a perspective bottom view of the cover shown in FIG. 9A;

FIG. 9C is a side sectional view of the cover shown in FIGS. 9A and 9B;

FIG. 9D is a plan view of a net for forming a cover according to another arrangement of the present disclosure;

FIG. 10A is an exploded view of an assembly comprising the cover shown in FIGS. 9A to 9C and the SFP cage shown in FIG. 3A;

FIG. 10B is side perspective sectional view of the assembly shown in FIG. 10A;

FIG. 10C is front perspective view of the assembly shown in FIG. 10A with a signal connector installed in the SFP cage;

FIG. 11A is a rear perspective view a cover according to another arrangement of the present disclosure;

FIG. 11B is a front perspective view of an assembly comprising an SPF cage and the cover shown in FIG. 11A;

FIG. 12A is a perspective view of a signal connector extender assembly comprising a SFP cage assembly according to arrangements of the present disclosure;

FIG. 12B is a side sectional view of the assembly shown in FIG. 16;

FIG. 13 is a perspective view of plurality of the SFP cages and covers shown in FIGS. 8A and 8B;

FIG. 14 is a front view of an assembly comprising the plurality of the SFP cages and covers, and a heat sink according to arrangements of the present disclosure;

FIG. 15 is a top perspective exploded view of a multi-slot SFP cage assembly according to arrangements of the present disclosure;

FIG. 16A is a top perspective view of a cover for a multi-slot SFP cage according to arrangements of the present disclosure;

FIG. 16B is a bottom perspective view of the cover shown in FIG. 16A; and FIG. 16C is a plan view of a net to be formed into the cover shown in FIGS. 16A and 16B.

### DETAILED DESCRIPTION

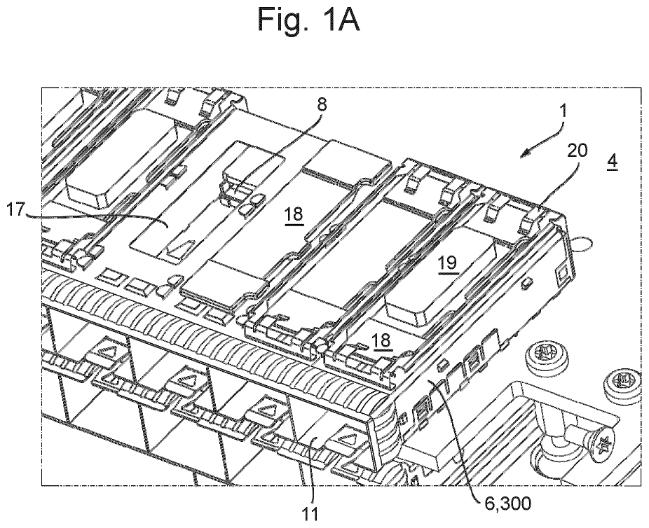

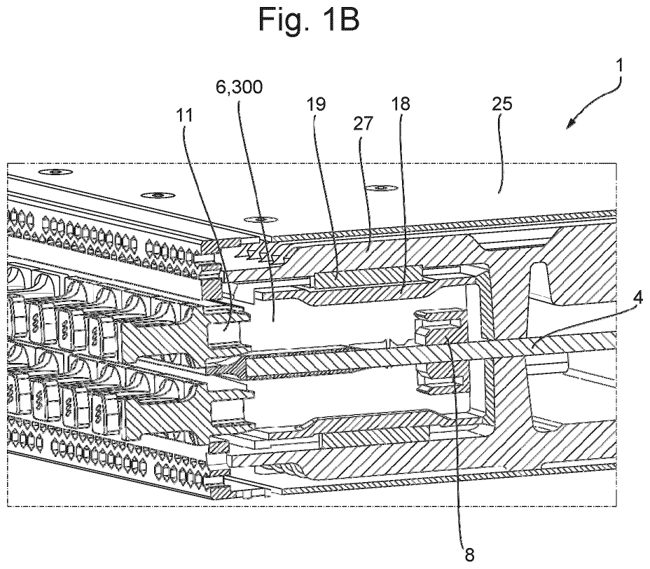

FIGS. 1A and 1B show a conventional interface module 1, comprising a plurality of cages 6 for receiving pluggable signal connectors. In FIG. 1A, the interface module 1 is mounted on a printed circuit board (PCB) 4. In FIG. 1B, a main unit assembly comprises a pair of interface modules 1 (shown in partial cutaway) mounted on a PCB 4. Heat sinks 25 including heat sink fins 27 are attached to the interface module 1.

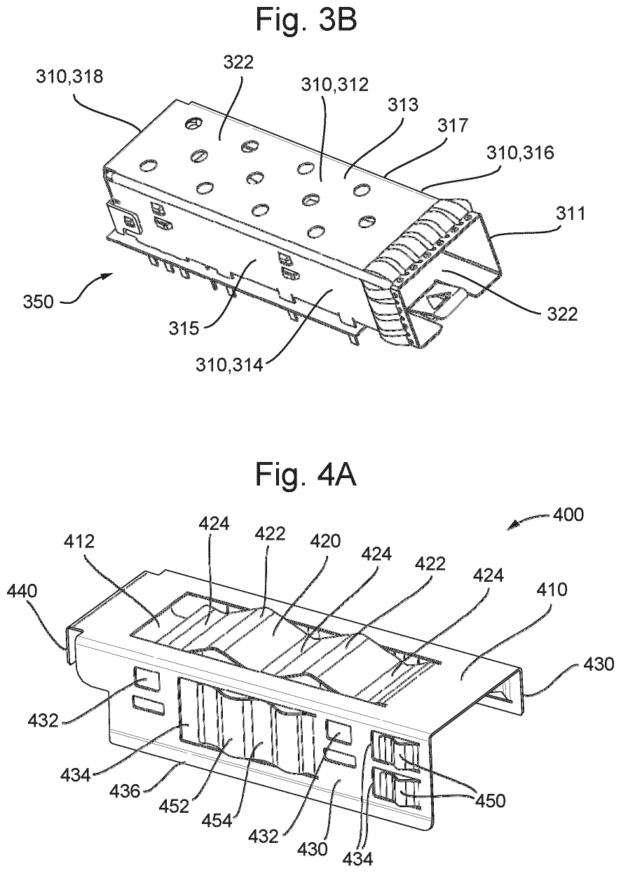

The cages 6 shown in FIGS. 1A and 1B may comprise a cage 300, e.g. a Small Form factor Pluggable (SFP) cage, such as that depicted in FIG. 3A. As shown in FIG. 3A, the cage 300 comprises a number of walls 310, such as an upper wall 312 and two opposing side walls 314, 316. The side walls 314, 316 may be arranged at an angle, e.g. perpendicular, to the upper wall 312 and may depend from either lateral side of the upper wall 312. In this way, the walls 310 of the cage 300 may enclose an interior space 322 for receiving a pluggable signal connector, such as a pluggable optical transceiver module. When the cage 300 is coupled to a PCB 4, e.g. within the assemblies shown in FIGS. 1A and 1B, the cage may be coupled to the PCB on a side of the cage opposite the upper wall, e.g. a bottom side of the cage. The upper side of the cage may refer to a side of the cage opposite the side of the cage 300 that is mounted on a base, such as the PCB 4.

The upper wall 312 and the side walls 314, 316 may form upper and side surfaces 313, 315, 317 of the cage 300 respectively. The cage 300, e.g. the walls 310 of the cage, may define an opening 311 at a front end of the cage into the interior space 322. In use of the interface module 1, a pluggable connector may be inserted through the opening 311 into the interior space 322. The cage 300 may be configured to guide the pluggable connector towards interface 8 positioned at or towards a rear of the cage 300, e.g. an opposite end of the cage from the opening 311. The interface 8 provides a connection to electronic circuitry, e.g. on a base or PCB 4. The interface 8 may possess a shape and structure that is complementary to a corresponding shape and structure of a connector (not shown). When the connector is fully inserted into the cage 6, 300, the connector mates with the interface 8. This allows signals to pass from the connector to the PCB 4 via the interface 8, or from the PCB 4 to the connector via the interface 8. A rear wall 318 may be provided at an end of the cage 300 opposite the opening 311. The rear wall 318 may define a rear surface 319 of the cage 300. The walls 310 of the cage, e.g. the upper, side and rear walls 312, 314, 316, 318. may together form a cage body 320 of the cage 300.

As depicted in FIGS. 1A, 1B and 3A, the cage body 320 may comprise an upper aperture 17, 323, e.g. in the upper surface 313 of the cage 6, 300. In some examples, the upper aperture 17, 323 may be a majority part of the upper surface of the cage 6, 300. For example, the upper aperture 323 may be formed in the upper wall 312. In the conventional example shown in FIG. 1A, an SFP heat sink 18 is located over the upper aperture 17. On top of the SFP heat sink 18, a thermal pad 19 is attached. The thermal pad 19 is arranged to put the SFP heat sink in thermal connection with a main unit heat sink 25, shown in FIG. 1B. A dedicated spring, or clip, 20 is used to hold the SFP heat sink in place. The main unit heat sink may be manufactured from a material having a high thermal conductivity, and may include one or more fins 27 or other features designed to dissipate heat. As shown in FIG. 1B, the fins 27 may extend in a direction parallel to the longitudinal direction of the openings 11. That is, the fins 27 may extend in the same direction in which a connector is inserted into the openings 11.

Aspects of the present disclosure recognise that thermal management for optical components, e.g. a DWDM SFP, can be improved on standard open frame cages on which are anchored a heat sink 18 through a dedicated spring/clip 20. In such arrangements, the heat sink must be kept in position with the dedicated spring and so requires a manual operation for assembly of the unit. Further, the thickness of this solution limits the height available for other components, e.g. heat dissipating fins 27 on the main heat sink 25. The interface module may be suitable for use in a computerized or processing apparatus, such as a networked computer, server or a network node for a telecommunications network.

With reference to FIG. 3B, in other arrangements an enclosed cage 350 may alternatively be used to receive a connector (e.g. the SFP connector). The enclosed cage 350 may be similar to the cage 300, except that the upper aperture 323 may be omitted. Accordingly, the SPF heatsink 18 may not extend through the upper aperture.

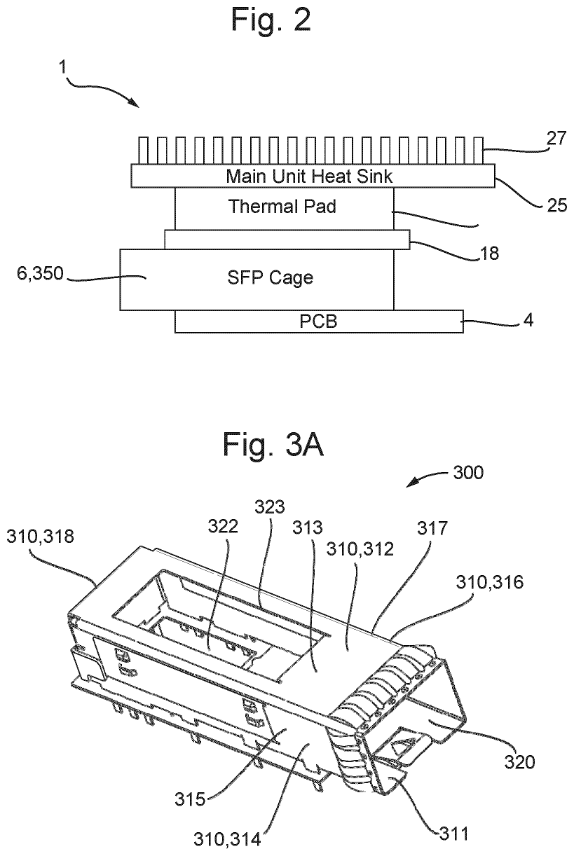

FIG. 2 is a schematic diagram of a conventional arrangement of an SFP cage 6, 350 of an interface module 1, a PCB 4 and a heat sink 25 including heat sink fins 27. The SFP cage 6, 350 contacts main unit heat sink 25 through an SFP heat sink 18 and a thermal pad 19. Alternatively, the heat sink 18 maybe omitted and the thermal pad 19 may be arranged in direct contact with the upper wall 312 of the cage. The SFP heat sink 18 and the thermal pad 19 provide a thermal path to allow heat to flow from the SFP cage 6 to the main unit heat sink 25, but also provide some thermal resistance to heat flow therebetween. Moreover, the SFP heat sink 18 and the thermal pad 19 take up significant space within the thickness of the main unit, which is constrained due to the available space within a rack in which it is configured to be mounted (e.g., 1 rack unit, or RU).

As described herein, the arrangements of the present disclosure may also be used together with the enclosed cage 350, in order to improve thermal management of interface modules comprising such cages.

Aspects of the present disclosure provide for modified components providing for improved thermal dissipation of heat from a connector (e.g. an SFP connector) to a heat sink of the interface module.

The conventional arrangement illustrated in FIGS. 1A, 1B and 2 may have certain drawbacks. For example, the conventional arrangement includes two heat sinks (i.e., a main unit heat sink and an SFP heat sink) connected with a thermal pad. This arrangement may increase thermal resistance, which can reduce heat dissipation. In addition, the conventional arrangement may require many different components to be used, since the SFP heat sink may be kept in position with a dedicated spring. The large number of components increases manufacturing cost and complexity.

Moreover, the thickness of the conventional arrangement may limit the height of the main heat sink fin (since the maximum allowed dimension is 1 RU). With a lower height fin, the thermal management of the system is worsened, and more powerful fan trays may be required. That has the drawback of increasing of the overall unit power consumption and noise.

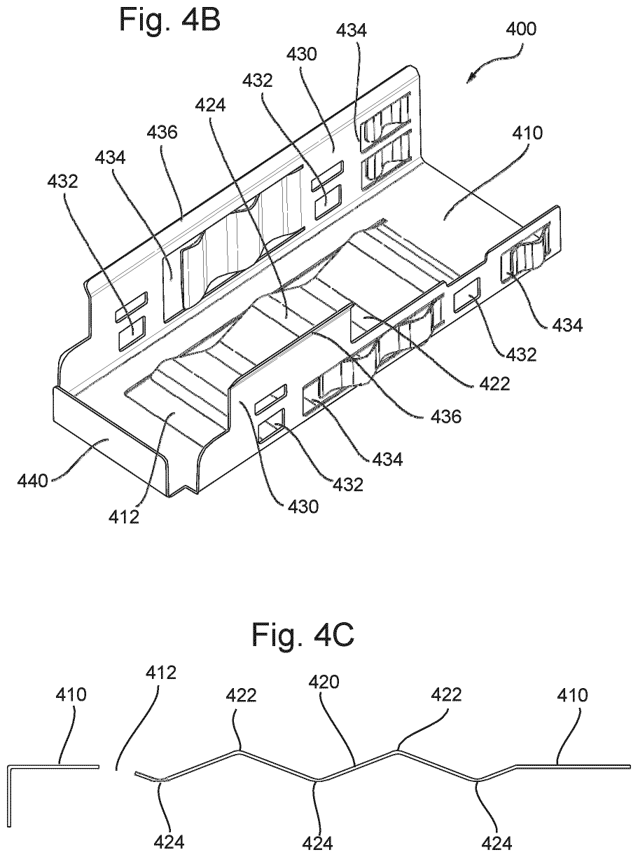

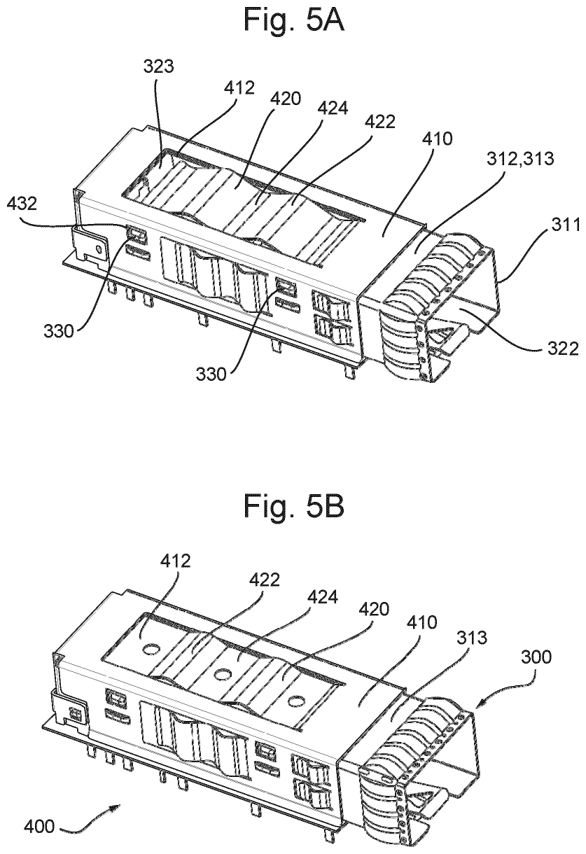

With reference to FIGS. 4A, 4B, 4C, 5A and 5B, a cover 400 for a cage 6, 300, 350, for receiving a signal connector, e.g. a pluggable signal connector, such as an SFP connector, according to arrangements of the present disclosure, will now be described. The cover 400 is attachable to a first surface of the cage 6, 300, 350, e.g. the upper surface 313, for thermally coupling the cage 6, 350 or a signal connector received within the cage 6, 300, to a heat sink, such as the heat sink 25 disposed outside the cage 6, 300, 350.

The cover 400 comprises an interface portion 410 engageable with the first surface of the cage 6, 300, 350, such as the upper surface 313. As depicted, the interface portion 410 may comprise a plate, configured, e.g. shaped, to be placed against the upper wall 312 of the cage such that the interface portion 410 is in contact with the upper wall 322 over a majority potion of the area of the interface portion and/or upper wall. The interface portion may be substantially planar and/or may be shaped to conform to a shape of the cage to which it is attached. The interface portion 410 may extend from a front end 402 of the cover to be arranged adjacent to the opening 311 of the cage 300 to a rear end 404 of the cover, to be position at an opposite end of the cage from the opening 311. The cover 400 further comprises an opening 412 formed in the interface portion 410.

As shown in FIG. 5A, the opening 412 may be arranged such that, when the cover 400 is attached to the upper surface 313 of the cage 300, the opening 412 at least partially overlaps the aperture 17, 317 formed in the upper surface of the cage.

The cover 400 further comprises one or more thermal coupling members 420. The thermal coupling members 420 are resiliently connected to the interface portion 410, the thermal coupling members 420 may thereby be resiliently deformable relative to the interface portion 410. As depicted, the thermal coupling members 420 extend at least partially across the opening 412.

Referring particularly to FIG. 4C, in an undeformed condition of the thermal coupling members 420, e.g. when the thermal coupling members are not being urged by the signal connector in the manner described below, one or more first portions 422 of the one or more thermal coupling members are disposed on a first side of the interface portion 410 and one or more second portions 424 of the one or more thermal coupling members are disposed on a second side of the interface portion 410 opposite the first side. As depicted, the thermal coupling member 420 may extend through the opening 412 in the interface portion to the second side of the interface portion, e.g. between the first and second portions 422, 424. In some examples, the one or more second portions 424 extend within a volume of the cage, when the signal connector is not present in the cage, i.e. in the undeformed condition. Insertion of the signal connector, e.g. SFP plug, urges the one or more second portions 424 outwardly. This outward movement urges the one or more first portions 422 into contact with the heatsink. Thus, the signal connector is thermally connected to the heat sink, i.e. via the thermal coupling member 420.

As shown in FIG. 5A, when the cover 400 is attached to the cage 300, one or more of the second portions 424 may extend through the aperture 323 formed in the first surface 313 of the cage, such that the second portions 424 are at least partially disposed within the interior space 322 of the cage. Referring to FIG. 5B, it will be appreciated, that when the cover 400 is attached to the cage 350 illustrated in FIG. 3B, no aperture is provided, and hence, the second portions 424 may not extend into the interior space 322 but may be in contact with the upper surface 313 of the cage. In such arrangements, attaching the cover 400 to the cage 300 may cause the thermal coupling member to be deformed, such that the thermal coupling member does not protrude beyond the second side of the interface portion, e.g. due to the presence of the upper surface 313 of the cage.

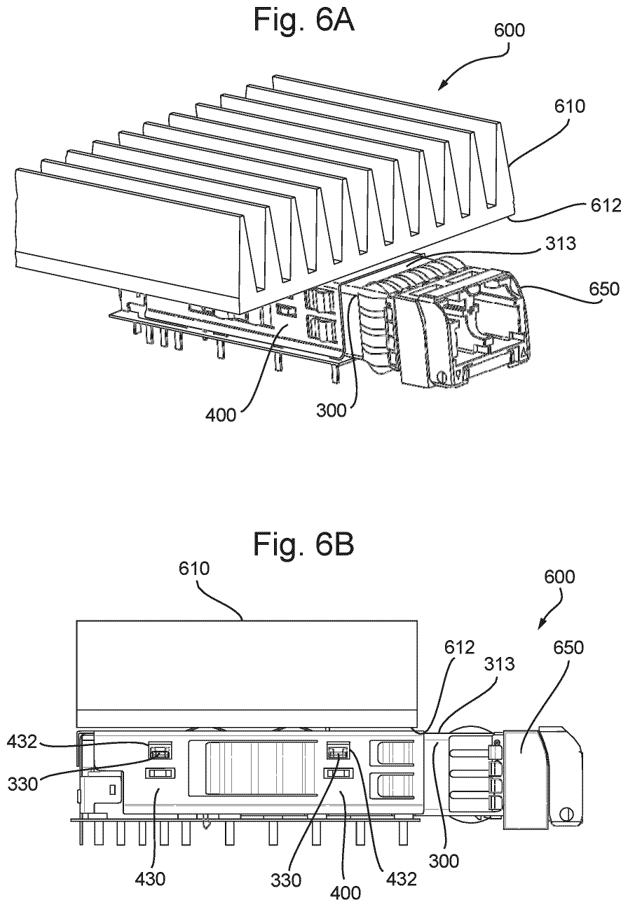

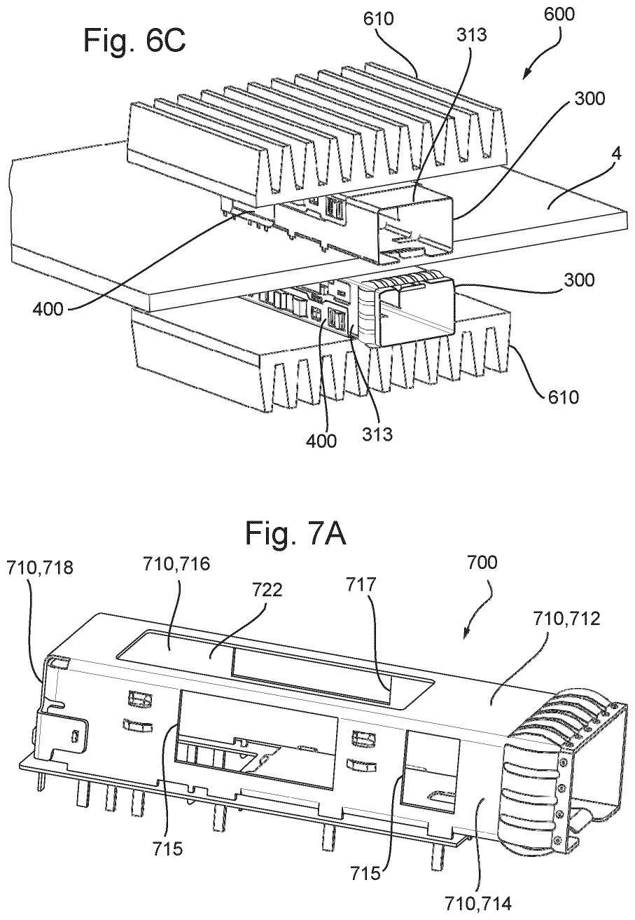

FIGS. 6A and 6B illustrate a cage assembly 600 according to the present disclosure, the cage assembly 600 comprising a cage, e.g. the SFP cage 300 and the cover 400, attached to the cage 300. As depicted, the assembly 600 may also comprise a heat sink 610 according to arrangements of the present disclosure. The heat sink 610 comprises a heat sink surface 612 spaced apart from the first surface 313 of the cage 300. As depicted, the heat sink surface 612 may be substantially parallel with the first surface 313 of the cage. In some arrangements, the assembly 600 may comprise a PCB 4 (shown in FIG. 6C), to which the cage 300 is connected on an opposite side of the cage 300 from the heatsink 610, in a similar way to in the arrangement shown in FIG. 1A. As illustrated in FIG. 6C, in some arrangements, a cage 300 comprising a cover 400 may be coupled on either side of a PCB 4. The cages 300 may be coupled to the PCB 4 in a belly-to-belly or arrangement, such that the upper surface 313 of each cage is positioned on the opposite side of the cage 300 from the PCB. As depicted, a further heat sink 610 may be provided on either side of the PCB, the heat sinks may be arranged such that the heat sink surfaces of each heat sink are parallel with and spaced apart from the upper surface 313 of the cage on the respective sides of the PCB 4.

When a signal connector 650 is inserted into the cage 300 with the cover 400 attached, as illustrated in FIGS. 6A and 6B, the signal connector 650 engages one or more of the second portions 424 of the thermal coupling members within the interior space 322 of the cage and urges the one or more second portions towards the first side of the interface portion 410. For example, the signal connector 650 may resiliently deform the thermal coupling member 420 relative to the interface portion 410. In this way, the thermal coupling members 420 are urged towards the heat sink, e.g. the surface 612 of the heat sink. When the signal connector 650 is installed within the interior space, the thermal coupling member may be urged, e.g. resiliently deformed, such that the thermal coupling member 420, e.g. the one or more first portions 422, contacts the heat sink. In some arrangements, the thermal coupling members 420 may be compressed between the signal connector 650 and the heat sink 610, when the signal connector 650 is received within the interior space 322.

When the cover 400 is attached to the cage 350 within the assembly 600, the thermal coupling members may be compressed between the cage 350 and the heat sink 610, and may thermally couple the cage to the heat sink 610.

In the arrangement shown in FIGS. 4A, 4B and 4C, thermal coupling member 420 comprises a corrugated or undulating plate comprising a plurality of alternating ridges and valleys. The ridges and valleys may alternatingly extend through the opening 412 to the first and second sides of the interface portion 410 and, when the cover 400 is attached to the cage 6, 300, through the aperture 323. As depicted, the ridges and valleys may extend in a transverse direction that is perpendicular to the longitudinal direction cover extending from the front end 402 to the rear end 404 of the cover. When the cover is attached to the cage, the transverse direction may be perpendicular to a longitudinal direction of the cage in which the signal connector can be inserted into the cage 6, 300, e.g. through the opening 311. The ridges and valleys may be formed by linear bends in the thermal coupling member 420 arranged parallel with the transverse direction.

As depicted, the thermal coupling member 420 may comprise a plate portion that is separated from the interface portion 410, e.g. the plate forming the interface portion, along three edges of the thermal coupling member. In other words, the thermal coupling member 420 may be formed by a portion of the plate forming the interface portion 410, which has been separated from the interface portion to form the opening 412 in the interface portion. The thermal coupling member 420 may remain attached to the interface portion 410 along an edge of the opening 412 closest to the front end 402 e.g. which is the edge closest to the opening 311 into the interior space of the cage. The edge along which the thermal coupling member 420 may remain attached to the interface portion 410 may be perpendicular to the longitudinal direction. In this way, the thermal coupling members 420 may be configured, e.g. shaped, to facilitate displacement of the thermal coupling members 420 by the signal connector as it is inserted into the cage.

In the arrangement depicted in FIGS. 4A to 4C, the thermal coupling member 420 is integrally formed within the interface portion 410. However, in other arrangements the interface portion 410 and the thermal coupling members 420 may be separate components coupled, e.g. mechanically coupled, together. Further, although the depicted arrangements comprise a single thermal coupling member 420, in other arrangements, the cover 400 may comprise a plurality of the thermal coupling members 420.

The cover 400, e.g. the thermal coupling members 420 of the cover, may comprise a thermally conductive material, such as a metal material, e.g. steel, aluminium, copper or alloys thereof, or any other suitable thermally conductive material. Hence, when the signal connector 650 is received within the interior space 322 defined by the cage 6, 300, 350 the signal connector 650 may be thermally connected to the heat sink 610 by the thermal coupling members 420 of the cover 400.

A thickness of the cover 400, e.g. between the cage and the heatsink, e.g. when the thermal coupling members 420 are compressed between the signal connector 650 and the heat sink 610, may be less than a thickness of the heat sink 18 and thermal pad 19 depicted in FIGS. 1A and 2. A height of heat sink fins 624 may therefore be made greater, without increasing a total height of the assembly 600 compared to the conventional arrangement shown in FIGS. 1A, 1B and 2.

Furthermore, when the thermal coupling members 420 comprise an electrically conductive material, the cover 400 may provide an electrical connection between the signal connector 650 and the heat sink 620, which may improve electromagnetic interference shielding of the signal connector 650 within the assembly 600.

Returning to FIGS. 4A to 4C, the cover 400 may further comprise one or more side interface portions 430, e.g. plate portions, for engaging one or more, e.g. respective, side surfaces 315, 317 of the cage 6, 300, 350. For example, the one or more side interface portions 430 may be configured to engage the one or more side surface 315, 317 of the cage 6, 300, 350 when the cover 400 is attached to the cage 6, 300, 350. As depicted, the one or more side interface portions 430 may be arranged at angles, e.g. perpendicular, relative to the interface portion 410. The side interface portions 430 may depend from one or more lateral sides of the interface portion 410, to engage the side surfaces 315, 317 of the cage, when the interface portion 410 of the cover engages the upper surface 313 of the cage.

As depicted, the side interface portions 430 may comprise one or more hook apertures 632 for hooks 330 (shown in FIGS. 5A and 5B) formed on the cage 6, 300, 350, e.g. on side surfaces 315, 317 of the cage, to protrude through when the cover 400 is attached to the cage. The hooks 330 of the cage may engage the hook apertures 632, which may secure the cover 400 onto the cage, e.g. to resist detachment of the cover 400 from the cage 6, 300, 350 or movement of the cover 400 relative to the cage.

Distal ends of the side interface portions 430 may comprise outwardly angled portions 434 extending along the distal edges of the side interface portions 430. The outwardly angled portions on each side interface portion 430 may be angled away from the side interface portion 430 on the opposite lateral side of the cover 400. The outwardly angled distal portions 436 of the side interface portions 430 may thereby be configured to ease installation of the cover over the cage. In particular, the outwardly angled distal portions 436 may engage the hooks 330 formed on the side surfaces 315, 317 of the cage and urge the side interface portions outwards, e.g. away from one another, so that the cover 400 can be installed down over the cage 300, 350 until the hooks 330 become received within the hook apertures 632. The side interface portions 430 may be resiliently deformable relative to the interface portion 410 to support this displacement during assembly.

The cover 400 may further comprise a rear interface portion 440, e.g. plate portion, for engaging the rear surface 319 of the cage 6, 300, 350 when the cover is attached to the cage. As depicted, the rear interface portion may depend from the rear edge of the interface portion, e.g. an edge perpendicular to the lateral sides of the interface portion. The rear interface portion 400 may extend from the interface portion in a direction parallel with the direction in which the side interface portions depend, e.g. perpendicular to the interface portion. The rear interface portion 400 may be configured to engage a surface of the cage 6, 300, 350 arranged at an angle, e.g. perpendicular to the longitudinal direction of the cage, e.g. the rear surface 319, for locating the cover in a longitudinal direction of the cage and/or restricting movement of the cover 400 in the longitudinal direction of the cage 6, 300, 350.

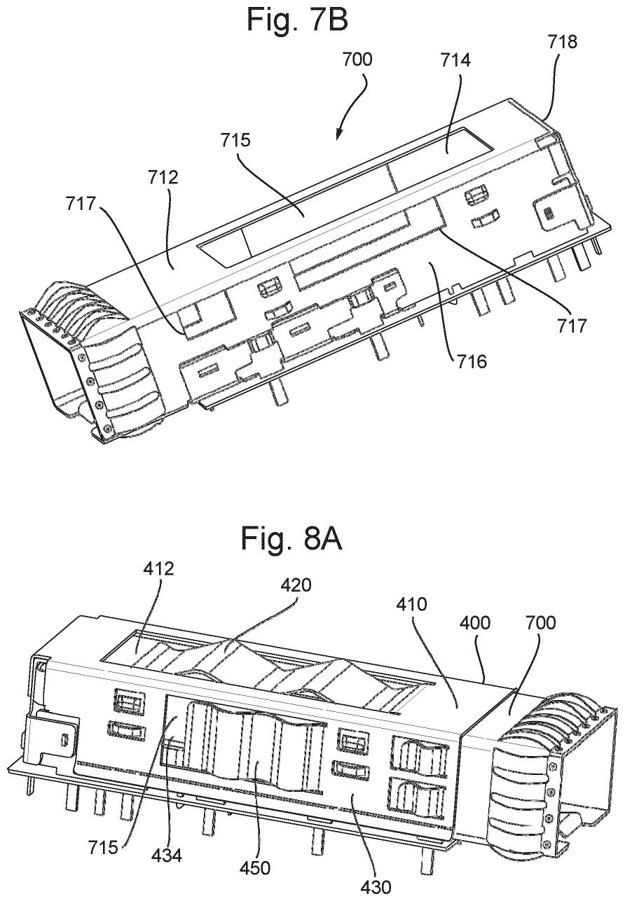

FIGS. 7A and 7B depict a cage 700 according to arrangements of the present disclosure. The cage 700 is similar to the cage 300 and comprises walls 710, which are similar to the walls 310. In particular, the walls may comprise an upper wall 712, two opposing side walls 714, 716 and a rear wall 718. The walls of the cage 700 may define an interior space 722 for receiving a pluggable signal connector, such as the SFP connector 650 mentioned above, through an opening 711 formed by edges of the upper and side walls at a front side of the cage.

The cage 700 differs from the cage 6, 300, 350 in that the cage 700 further comprises side apertures 715, 717 formed in the side walls 714, 716 respectively. The side apertures may extend through the side walls 714, 716 into the interior space 722.

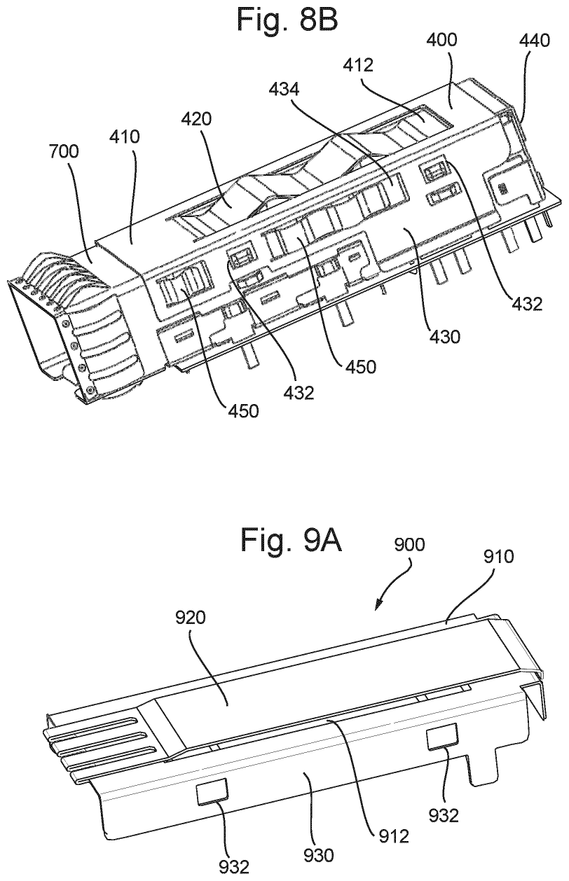

Referring to FIGS. 4A to 4C, and 8A and 8B, the cover 400 may comprise side openings 434 formed in the side interface portions 430, which may be at least partially aligned, e.g. at least partially overlap, the side apertures 715, 717 when the cover is attached to the cage 700. The cover 400 may further comprise one or more side thermal coupling members 450 resiliently connected to one or more of the side interface portions.

The side thermal coupling members 450 may extend at least partially across one or more, e.g. respective ones, of the side opening 434. For example, the cover 400 may comprise a side thermal coupling member 450 corresponding to each side openings 434. The side thermal coupling members 450 may extend at least partially through the side openings 434 and, when the cover 400 is attached to the cage 700 may extend through one of the side aperture 715, 717, e.g. the one of the side apertures with which the corresponding side opening 454 is aligned. Hence, when a signal connector is received within the interior space 722, the side thermal coupling members 450 may engage the sides of the signal connector. When the signal connector 650 is received within the interior space 722 of the cage 700, the signal connector may urge the side thermal coupling members 450 outwardly, e.g. by resiliently deforming the side thermal coupling members.

As depicted, the side thermal coupling member 450 may be configured similarly to the thermal coupling members 420 and may comprise one or more first portions 452 and one or more second portions 454. In an undeformed condition of the side thermal coupling members 450, the one or more fist portions 452 may be disposed on a first side of the side interface portion 450 and the one or more second portions 454 may be disposed on a second side of the side interface portion opposite the first side. Prior to the signal connector being installed within the cage 700, the second portions 454 may be at least partially received within the interior space 722 of the cage 700. For example, the second portions 454 may extend at least partially through the side openings 434 and the side apertures 715.

As shown in FIGS. 7A to 8B, the cage 700 may comprise two side apertures formed in each side wall 714, 716. Alternatively, a different number of side apertures 715, 717 may be formed in in each side wall of 714, 716 the cage 700. For example, two side apertures 715 may be formed in one side wall 714 and three side apertures 717 may be formed in the other side wall 716. Additionally or alternatively, a different number of side openings 434 and side thermal coupling members 450 may be formed on each of side interface portions of the cover 400. The number of side openings 434 and side thermal coupling members 650 may correspond to the numbers of side apertures 714, 717 formed in the side walls of the cage 700. Alternatively, there may be a different number of side opening and thermal coupling members to side apertures. For example, more than one of the side openings in the cover may align with a single one of the side apertures 715, 717 in the cage, or vice versa.

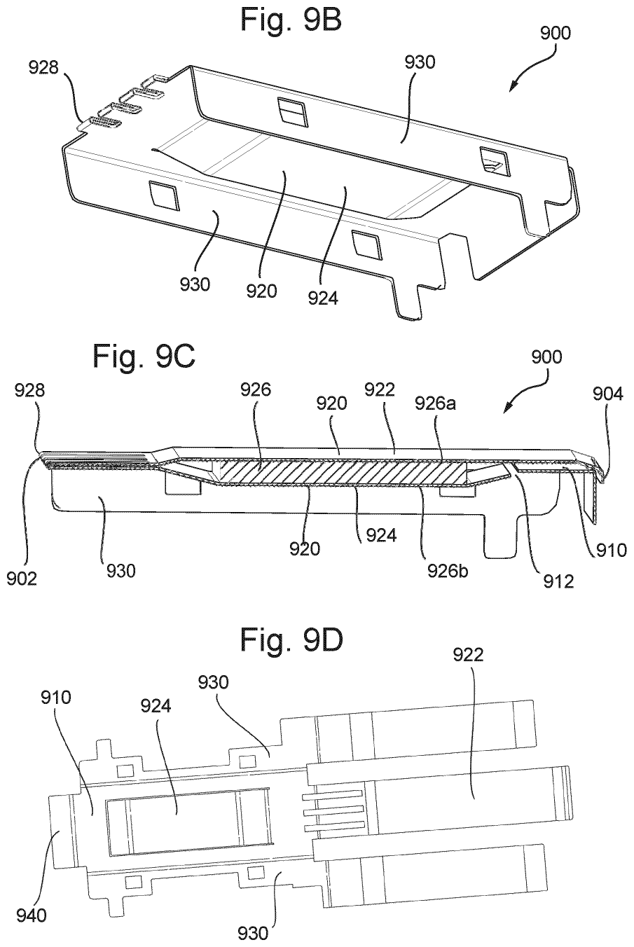

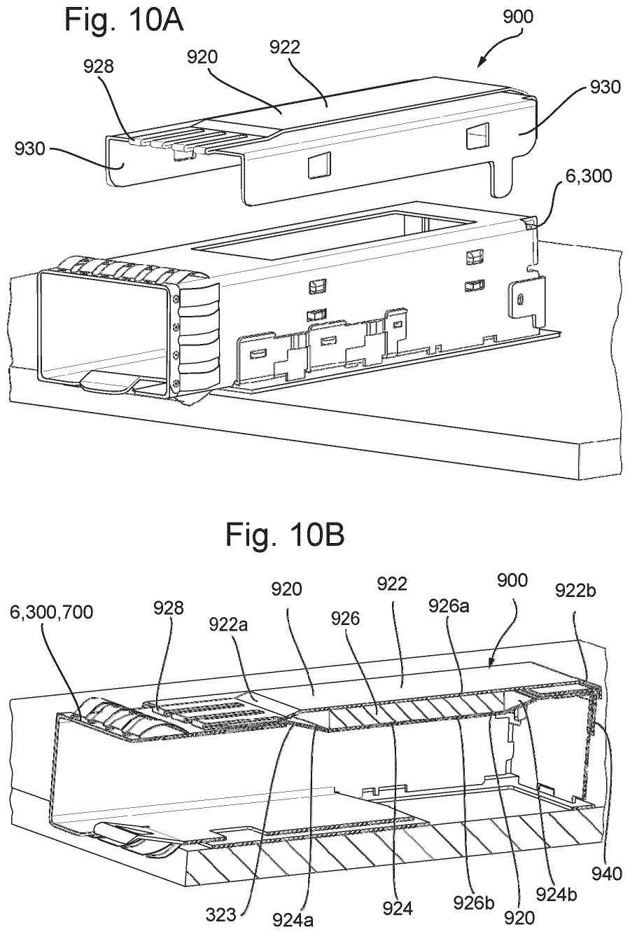

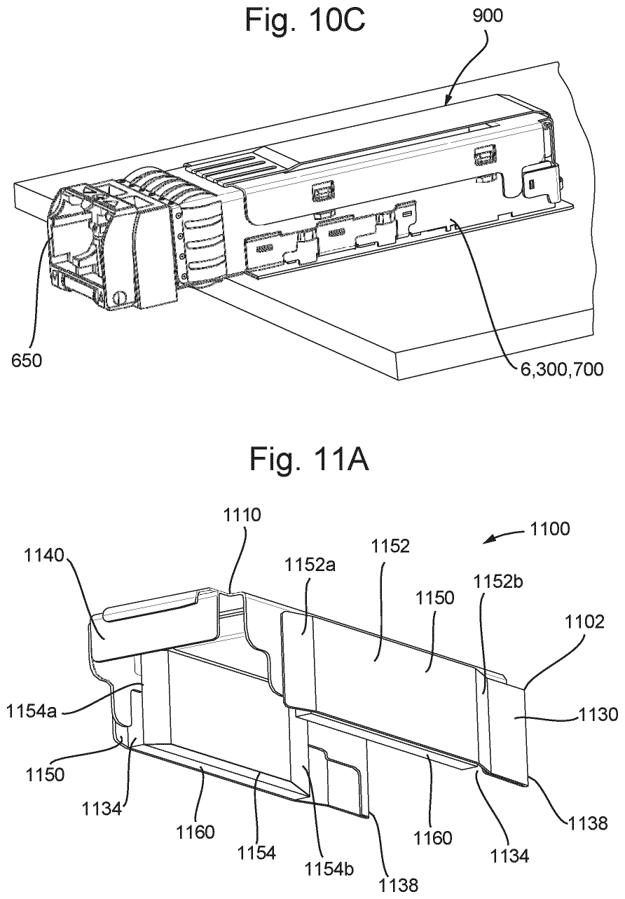

FIGS. 9A, 9B, 9C, 10A and 10B depict a cover 900 according to another arrangement of the disclosure. The cover 900 is similar to the cover 400 and comprises an interface portion 91, engageable with the first surface of the cage 6, 300, 350, 700, such as the upper surface 313 when the cover 900 is attached to the cage. Similarly to the interface portion 410, the interface portion 910 may comprise a plate, e.g. a substantially planar plate, configured to be placed against the upper surface 313 of the cage when the cover 900 is attached to the cage, such that the interface portion 910 is in contact with the upper wall 322 over a majority portion of the area of the interface portion.

The cover 900 may further comprise side interface portions 930, which are configured similarly to the side interface portions 430 of the cover 400. In particular, the side interface portions 930 may depend from lateral sides of the interface portion at angles, e.g. perpendicular, to the interface portion 930 and may be for engaging side surfaces 315, 317 of the cage 6, 300, 350, 700, when the cover 900 is attached to the cage. The side interface portions 930 may comprise hook apertures 932 through which hooks 330 on the cage can extend to secure the cover 900 over the cage. The cover 900 may further comprise a rear interface portion 940 configures similarly to the rear interface portion 440 of the cover 400.

The cover 900 further comprises an opening 912 formed in the interface portion 910. The opening 912 may be arranged similarly to the opening 412 formed in the interface portion 410. In particular, the opening 912 may be arranged such that when the cover 900 is attached to the first surface, e.g. the upper surface 313 of the cage 6, 300, 700, the opening 912 at least partially overlaps the aperture 317 formed in the upper surface of the cage.

The cover 900 similarly comprises one or more thermal coupling members 920. The thermal coupling members 920 are resiliently connected to the interface portion 910 and may be resiliently deformable relative to the interface portion 910. The thermal coupling members 920 may extend at least partially across the openings 912.

Referring particularly to FIGS. 9c and 10B, in an undeformed condition of the thermal coupling members 920, one or more first portions 922 of the thermal coupling members are disposed on a first side of the interface portion 910 and one or more second portions 924 of the thermal coupling members 920 are disclosed on a second side of the interface portion 910 opposite the first side. When the cover 900 is attached to the cage 6, 300, 700 the second portion 924 of the thermal coupling members may extend through the aperture 323 formed in the upper surface 313, 713 into the interior space 322, 722.

As illustrated, the thermal coupling member 920 may further comprise a thermal pad 926 at least partially enclosed between the first and second portions 922, 924 of the thermal coupling member. In particular, the thermal pad 926 may be enclosed on an upper side 926a by the first portion 922 and enclosed on a lower side 926b by the second portion 924. As depicted, the thermal pad 926 may be disposed within the opening 912 and may extend through the opening between the first and second sides of the interface portion 910.

FIG. 9D shows a plan view of a net for forming the cover 900 from a sheet, e.g. a sheet of a metal material, such as steel, aluminium, copper or alloys thereof. As illustrated, the cover 900 (other than the thermal pad(s)) can be formed from a single folded sheet of material.

As can be seen from FIGS. 9A to 9D, the second portion 924 of the thermal coupling member may comprise a plate portion that is separated from the interface portion 710 along three edges of the second portion. The second portion 924 may remain attached to the interface portion 910 along an edge of the opening 912 closest to the opening 311, 711 into the interior space of the cage. In other words, the second portion 924 may comprise a portion of material cut from the plate forming the interface portion 910 to form the opening 912, which has then been deformed, e.g. bent, relative to the plate forming interface portion 910 to the second side the interface portion.

The first portion 922 of the thermal coupling member may comprise a portion of the sheet of material forming the cover, which extends from a bend 928 formed at or towards the front end 902 of the cover 900 back over the interface portion 910 and the opening 912 on the first side of the interface portion 910. As depicted, a portion of the cover 900 at which the bend 928 may comprise a plurality of longitudinally extending openings, such that the bend comprise a plurality of bent plate portions spaced laterally across the cover 900 joining the interface portion 910 and the first portion 924 of the thermal coupling member 920.

The first portion of 922 of the thermal coupling member may comprise a front ramp portion 922a and a rear ramp portion 922b. At the front ramp portion 922a a height of the first portion 922 relative to the interface portion 910, e.g. a distance that the first portion 922 extends to the first side of the interface portion 910 increases in a direction from the front 902 of the cover 900 towards the rear 904 of the cover. At the rear ramp portion 922b the height of the first portion 922 relative to the interface portion 910 decreases in the direction from the front of the cover 900 towards the rear of the cover. The ramp portions may thereby be configured to facilitate sliding of the cover 900, or a cage 6, 300, 350, 700 to which the cover is attached, relative to a heat sink during installation of the cover, cage adjacent the heat sink. Further, the ramp portion may encourage deformation of the thermal coupling member in order to compress the thermal pad 926 between the first and second portions of the thermal coupling member. As depicted, the front and rear ramp portions may be formed by bends, e.g. linear bend, extending laterally across the first portion 922.

The second portion 924 may similarly comprise a front ramp portion 924a and a rear ramp portion 924b. At the front ramp portion 924a a height of the second portion 924 relative to the interface portion 910, e.g. a distance that the second portion 924 extends relative to the second side of the interface portion 910 increases in a direction from the front 902 of the cover 900 towards the rear 904 of the cover. At the rear ramp portion 9242b the height of the second portion 924 relative to the interface portion 910 decreases in the direction from the front of the cover 900 towards the rear of the cover. The ramp portions may thereby be configured to facilitate sliding of the signal connector into the interior space within a cage to which the cover is attached, and to facilitate urging of the second portion of the thermal coupling members by the signal connector. As depicted, the front and rear ramp portions may be formed by bends, e.g. linear bends, extending laterally across the second portion 924.

The presence of the front and rear bend portions 922a, 922b, 924a, 924b of the first and second portions of the thermal coupling member may further reduce the risk of damage to the first and second portions 922, 924 and the thermal pad 926 when the cover 900 is slid relative to the heat sink and/or when the signal connector is installed into a cage to which the cover is attached, As depicted in FIG. 10C, when a signal connector 650 is installed within a cage 6, 300, 700 having the cover 900 attached, the signal connector 650 may engage the second portion 924 of the thermal coupling member and urge the second portion 924 upwards, e.g. towards the interface portion 910, through the opening 912.

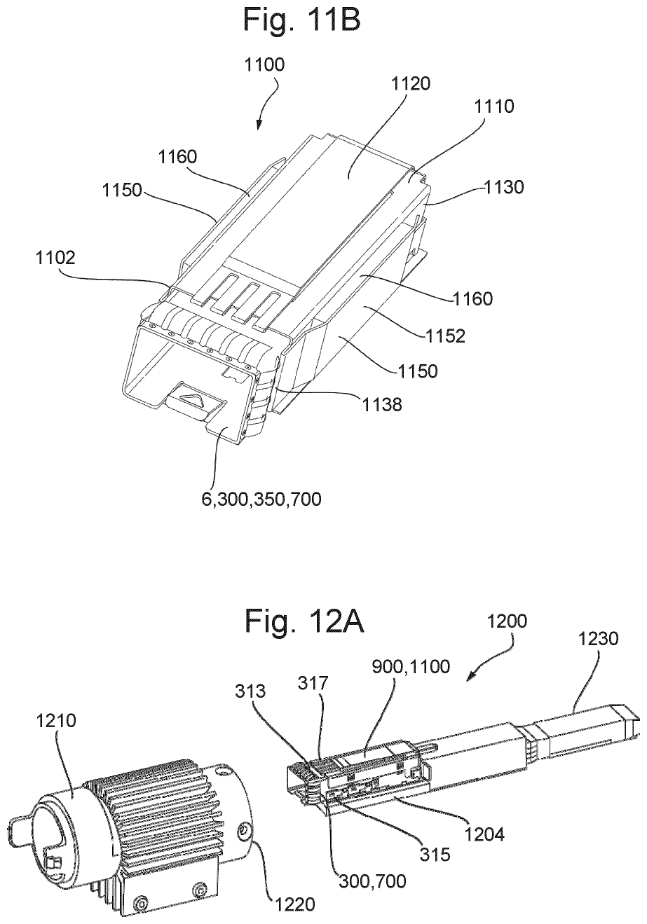

With reference to FIGS. 11A and 11B, a cover 1100 according to arrangements of the present disclosure will now be described. The cover 1100 is similar to the cover 900 described above, and comprises an interface portion 1110, side interface portions 1130, rear interface portion 1140 and thermal coupling members 1120, which are similar to the interface portion 910, side interface portions 930, rear interface portion 940 and thermal coupling members 920 of the cover 900 described above.

The cover 1100 differs from the cover 900 described above, in that the side interface portions 1130 further comprise one or more side openings 1134 formed in the side interface portions. The side openings 1134 may be formed in the side interface portions 1130 so as to be at least partially aligned with the side apertures 715, 717 in the cage 700, when the cover 1100 is attached to the cage 700. The cover 1100 may further comprise one or more side thermal coupling members 1150 resiliently connected to one or more of the side interface portions 1130.

The side thermal coupling members 1150 may extend at least partially across one or more, e.g. respective ones, of the side openings 1134. For example, the cover 1100 may comprise a side thermal coupling member 1150 corresponding to each of the side openings 1134. The side thermal coupling members 1134 and side openings may generally be similar to the openings and thermal coupling members provided on the interface portions, as described above. In particular, each of the side thermal coupling members may extend at least partially through one of the side openings 1134 and, when the cover 1100 is coupled to the cage 700, may extend through one of the side apertures 715, 717, e.g. the one of the side apertures with which the corresponding side opening 1134 is aligned. Alternatively, when the cover 1100 is attached to the enclosed cage 350, the side thermal coupling members 1150 may engage the side surfaces 313, 317 of the cage 350.

When a signal connector 650 is received within the interior space 322, 722 of the cage 6, 300, 350, 700 to which the cover 1100 is attached, the side thermal coupling members 1150 may engage the sides of the signal connector. When the signal connector 650 is received within the interior space 722 of the cage 700, the signal connector may urge the side thermal coupling members 1150 outwardly, e.g. by resiliently deforming the side thermal coupling members.

Each of the side thermal coupling member may comprise a first portion 1152 and a second portion 1154. In an undeformed condition of the side thermal coupling members 1150, the one or more first portions 1152 may be disposed on a first side of the side interface portion 1130 and one or more second portions 1154 of the side thermal coupling members 1150 may be disclosed on a second side of the side interface portion 1130 opposite the first side. The cover 1100 may further comprise one or more side thermal pads 1160, which may be at least partially enclosed between the first and second portions 1152, 1154 of respective ones of the side thermal coupling members 1150. For example, each of the side thermal coupling members may comprise a thermal pad enclosed between the first and second portions. The side thermal pads 1160 may be arranged at least partially within the side openings 1134.

The cover 1100 may comprise a different number of side openings 1134 and side thermal coupling members 1150 on each of side interface portions of the cover 1100, e.g. corresponding to the numbers of side apertures formed in the side walls of the cage 700 with which the respective side interface portions interface when the cover 1100 is attached to the cage 700.

The first and second portions of the side thermal coupling members 1132, 1134 may be formed in a similar way to the first and second portions 922, 924 described above. In particular, the second portion 924 may comprise a plate portion that has been separated from the plate forming the side interface portions that along three edges of the second portion. The second portion 1124 may remain attached to the side interface portion 1130 along an edge of the opening 1134 closest to the opening 311, 711 into the interior space of the cage. In other words, the second portion 1134 may comprise a portion of material cut from the plate forming the side interface portion 1130 to form the opening 1134, which has then been deformed, e.g. bent, relative to the plate forming side interface portion 1130 to the second side the interface portion.

The first portion 1132 of the side thermal coupling member 1130 may comprise a portion of the sheet of material forming the cover 110, which extends from a bend 1138 formed at or towards the front end 1102 of the cover 1100, back over the side interface portion 1130 and the opening 1134 on the first side of the side interface portion 1130.

The first and second portions of the side thermal coupling members may comprise front and rear ramp portions 1152a, 1152b, 1154a, 1154b which may be configured similarly to the front and rear ramp portions 922a, 922b, 924a, 924b formed in the first and second portions of the thermal coupling member 920 described above. The front and rear ramp portions formed in the first and second portions of the side thermal coupling members may similarly facilitate sliding of the cage relative to a heat sink and/or insertion of a signal connectors into a cage having the cover 1100 attached.

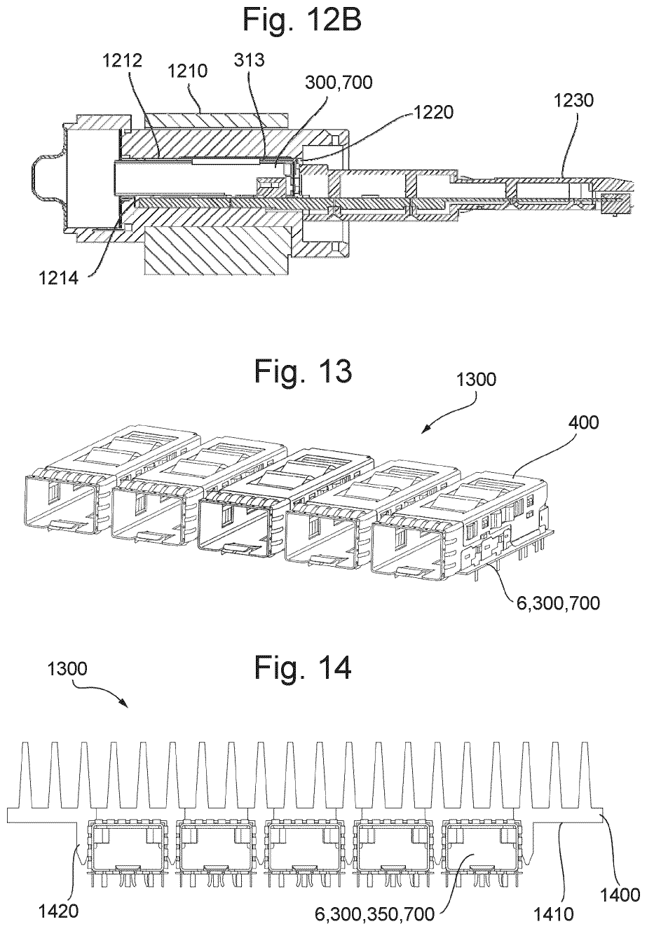

FIGS. 12A and 12B illustrate a cage assembly 1200 according to arrangements of the present disclosure, the assembly 1200 comprises the SFP cage 300, 700, the cover 900, 1100 and a heat sink 1210. The heat sink 1210 comprise a first heat sink surface 1212 which is parallel with and spaced apart from the upper surface 313 of the cage 300, 700 when the cage assembly 1200 is assembled. In some arrangements, the assembly 1200 may comprise a base or PCB 1204, to which the cage 300, 700 is connected on an opposite side of the cage 300 from the heatsink surface 1210.

When a signal connector 650 is inserted into the cage 300, 700 provided within the cage assembly 1200, the signal connector 650 engages one or more of the second portions 924, 1124 of the of the thermal coupling members 920, 1120 within the interior space 322, 722 and urges the one or more second portions towards the first side of the interface portion 910, 1110. In this way, the thermal coupling members 920, 1120 are urged towards the heat sink, e.g. the first heat sink surface 1212. In some arrangements, the thermal coupling members 920, 1120 may be compressed between the signal connector and the heat sink 1210 when the signal connector is received within the interior space 322, 722.

In some aspects, the cover and cage of any example are inserted together into contact with the heat sink. In some aspects, the cage and cover may be considered as forming a single unit, which can be inserted into, or in thermal contact with, a heat sink. A connector, e.g. SFP plug, may be inserted into the cover and cage before or after the cover and cage are inserted into, or in thermal contact with, a heat sink. In some examples the connector, e.g. SFP plug is first inserted into the combined cover and cage. The combined cover, cage and plug are then inserted into, or in thermal contact with, the heat sink.

In some arrangements, the heat sink 1210 further comprises one or more second heat sink surfaces 1214, which are parallel with and spaced apart from either or both of the side surfaces 315, 317 of the cage 700. When the assembly comprises the cover 1100, the signal connector 650 may engage one or more of the second portions 1154 of the side thermal coupling members 1150 of the cover 1100 within the interior space 722 and urge the one or more second portions towards the first sides of the corresponding side interface portions 1130. In this way, the side thermal coupling members 1150 may be urged towards the second heat sink surfaces 1214, when the signal connector is inserted into the cage 700. In some arrangements, the side thermal coupling members 1150 may be compressed between the signal connector 650 and the heat sink, e.g. the second heat sink surfaces 1214, when the signal connector is installed.

During assembly of the cage assembly 1200, the cage 300, 700 having the cover 900, 1100 attached may be slid into a heat sink opening 1220 in the heat sink, formed between the first and second heat sink surfaces 1212, 1214. As described above, the thermal coupling members 1120 and side thermal coupling members 1150 may be configured to facilitate sliding of the cover 900, 1100 relative to the heat sink without damage to the thermal pads 926 and side thermal pads 1160.

In some aspects, the cage assembly 1200 comprises a connector end 1230. The connector end is configured with the shape or form of the signal connector, e.g. SFP plug. The connector end 1230 is configured to be inserted into a cage configured to receive a signal connector. The connector end 1230 is configured to provide for an electrical output from the signal connector 650. The cage assembly 1200 provides for heat dissipation from the signal connector, e.g. comprising a transceiver, via the heatsink. Thus, the heatsink 1210 provides for effective removal of heat from the SFP plug (e.g. transceiver). For example, the heatsink may surround the signal connector on all lateral sides, e.g. provide a cylindrical heat sink on all lateral sides of the signal connector. The connector end 1230 provides for a connection to a cage for transmission or receiving a signal from/to the signal connector.

With reference to FIGS. 13 and 14, a cage assembly 1300 according to arrangements of the present disclosure comprises a plurality of the cages 6, 300, 350, 700 arranged side by side with one another, e.g. such that the side surfaces of each cage are spaced apart from the adjacent side surface of the adjacent cage or cages, and each of the side surfaces of the cages are parallel with one another. In some arrangements, the cages may be coupled to a PCB, (not shown). In the arrangement shown, each of the cages has a cover 400 attached to the first surface, e.g. the upper surface 313, of the cage. In the arrangements shown in FIGS. 13 and 14 it is the cover 400 depicted in FIGS. 4A to 4C attached to each of the cages 300, 350, 700. However, in other arrangements, any of the other covers described herein may be coupled to one, more than one or each of the cages in place of the cover 400.

As depicted in FIG. 14, the cage assembly 1200 may further comprise a heatsink 1400 according to arrangements of the present disclosure. As depicted, the heatsink 1400 may comprise a plurality of heatsink surfaces 1410 arranged parallel with and spaced apart from the upper surfaces 313 of the cages. In the same way as in the cage assembly 600 depicted in FIGS. 6A to 6C, the heat sink 1400 may be arranged such that when signal connectors 650 are installed within the cages 6, 300, 350, 700, the thermal coupling members 420 of the covers attached to the cages in which the signal connector are installed are urged towards the heat sink 1400, e.g. respective ones of the heat sink surfaces 1410. When the signal connectors are installed, the thermal coupling members 420 of the covers may be in contact with the signal connector 650 and the heatsink surfaces 1410, and may be compressed between the signal connectors and the heatsink surfaces.

As depicted in FIG. 14, the heatsink 1400 may comprise one or more projecting portions 1420, which project downwardly from the heatsink surfaces, e.g. in a direction towards the cages 6, 300, 350, 700. The projecting portion 1420 may be disposed between adjacent ones of the cages. In some arrangements, such as depicted in FIG. 14, projecting portions 1420 may be arranged to either side of each of the cages 6, 300, 350, 700. The projecting portions 1420 may be configured to contact the side thermal coupling members 450, e.g. second portions 454 of the side thermal coupling members, of the covers 400 arranged on either side of the respective projecting portions, e.g. when the signal connectors are installed within the cages. The projecting portions 1420 may be configured, and the cages may be arranged, such that the side thermal coupling portions are compressed between the signal connectors, or the side surfaces 315, 317 of the cages, and the projecting portions of the heatsink, e.g. when the signal connectors are installed within the cages.

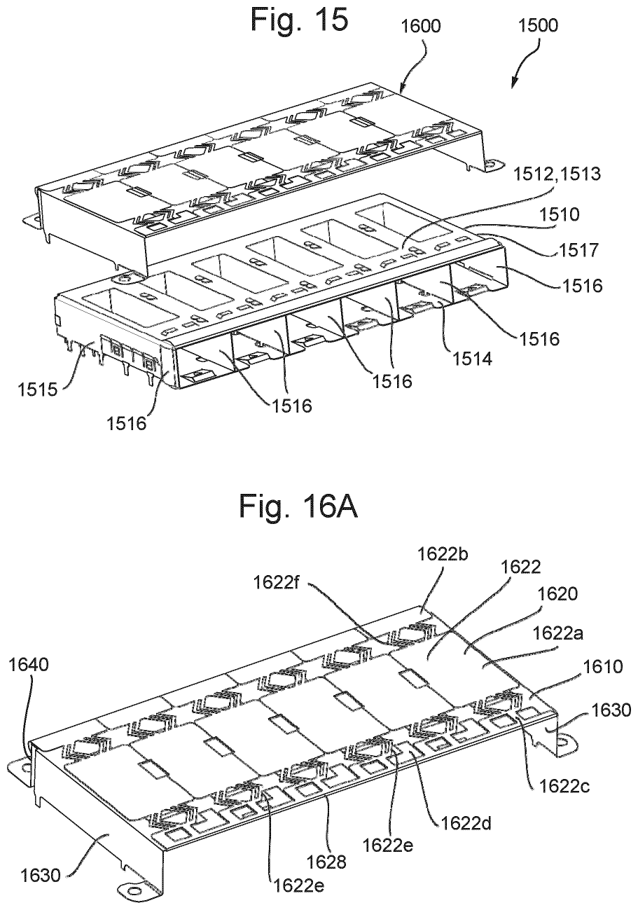

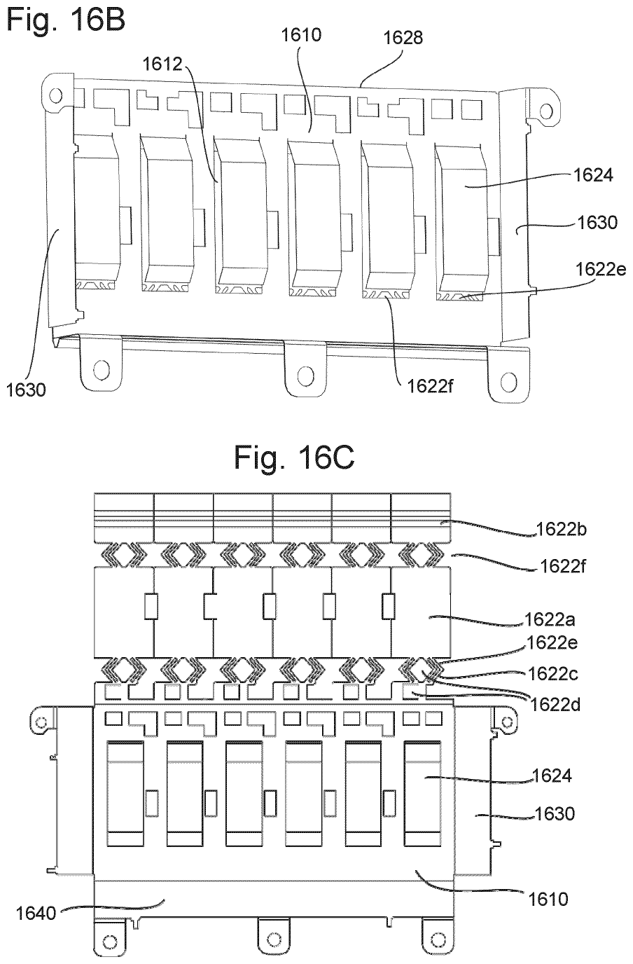

With reference to FIGS. 15, 16A, 16B and 16C, a cover assembly 1500 according to another arrangement of the present disclosure comprises a multi-slot cage 1510 and a cover 1600 for the multi-slot cage. As depicted, the multi-slot cage 1510 may be configured to receive a plurality of signal connectors, e.g. pluggable signal connectors, such as SFP connectors, in a side-by side arrangement.

As depicted, the multi-slot cage 1510 comprises a number of walls, such as an upper wall 1512, a lower wall 1514 opposite the upper wall, and a plurality of spaced apart side walls 1516 extending between the upper wall 1512 and the lower wall 1514 substantially perpendicular to the upper wall 1512 and the lower wall 1514. A plurality of internal spaces 1518 for receiving the signal connectors are formed between the upper wall 1512, the lower wall 1514 and each pair of adjacent side walls 1516.

The upper wall 1512 may form an upper surface 1513 of the multi-slot cage and ones of the side walls 1516 arranged at the extreme lateral sides of the multi-slot cage may form side surfaces 1515, 1517 of the multi-slot cage. The upper wall 1512 may comprise a plurality of apertures 1512a formed through the upper wall 1512 into respective ones of the internal spaces.

A cover 1600 according to another arrangement of the present disclosure, may be configured to be attached over the multi-slot cage 1510. As depicted, the cover 1600 may be generally similar to the covers 400, 900, 1100 described above. In particular, the cover comprises an interface portion 1610, which may comprise a plate, e.g. a substantially planar plate, engageable with the upper surface 1513 of the multi-slot cage 1500 when the cover 1600 is attached over the cage 1500. The interface portion 1610 may be configured to extend over a majority portion of the upper surface of the cage 1500. The cover 1600 further comprises side interface portions 1630, similar to the side interface portions 430, 930, 1130 for engaging the side surfaces 1515, 1517 of the multi-slot cage, and may comprise a rear interface portion 1640 for engaging a rear surface of the multi-slot cage.

The cover 1600 may comprise a plurality of openings 1612 formed in the interface portion 1610 of the cover. The openings 1612 may be spaced over the interface portion of the cover, such that one of the openings overlaps with each of the internal spaces 1518 in the cage 1500 configured to receive a signal connector, when the cover 1600 is attached to the multi-slot cage 1500, e.g. when the interface portion 1610 is attached over the upper surface 1512. For example, the openings 1612 may be configured to at least partially overlap with respective ones of the apertures 1512a. The cover 1400 further comprises a plurality of the thermal coupling members 1620 aligned with respective ones of the openings 1612.

The thermal coupling member 1620 of the cover 1600 may be configured in a similar way to the thermal coupling members 920, 1120 of the covers 900, 1100 described above and the features described in relation to the thermal coupling members 920, 1120 may apply equally to the thermal coupling members 1620. In particular, the thermal coupling members 920, 1120 may be resiliently coupled to the interface portion 1610 and may extend at least partially across respective ones of the openings 1612. The thermal coupling members 1620 comprise one or more first portions 1622 disposed on a first side of the interface portion 1610 and one or more second portions 1624 disposed on a second side of the interface portion. When the cover 1600 is attached to the multi-slot cage 1500, the second portions of the thermal coupling members 1620 may extend at least partially through respective ones of the openings into the interior spaces in the cage. The thermal coupling members 1620 may comprise thermal pads at least partially enclosed between the first and second portions of the thermal coupling members.

The first and second portions of the thermal coupling members may be formed similarly to the first and second portion of the thermal coupling members 922, 924, 1122, 1124 described above. In particular, the second portion 1624 of the thermal coupling member may comprise a plate portion that is separated from the interface portion 1610 along three edges of the second portion. The second portion 1624 may remain attached to the interface portion 1610 along an edge of the opening 1612 closest to the openings into the interior spaces of the cage 1500. In other words, the second portion 1624 may comprise a portion of material cut from the plate forming the interface portion 1610 to form the opening 1612, which has then been deformed, e.g. bent, relative to the plate forming interface portion 1610 to the second side the interface portion.

The first portion 1622 of the thermal coupling member may comprise a portion of the sheet of material forming the cover 1600, which extends from a bend 1628 formed at or towards the front end 1602 of the cover 1600 back over the interface portion 1610 and the opening 1612 on the first side of the interface portion 1610.

As depicted, each of the first portions 1622 may comprises a main plate part 1622a at least partially aligned with the opening 1612 across which the thermal coupling member extends. The main plate part may at least partially overlap a corresponding second portion 1624 and may be shaped to at least partially enclose a thermal pad received between the corresponding first and second portions. The first portions may further comprise a rear plate part 1622b, which extends around a corner of the cover between the interface portion and the rear interface portion of the cover.

The first portions 1622 may further comprise a front connecting part 1622c for connecting the main plate part 1622a to the interface portion 1610, e.g. at the bend 1628. For example, the front connecting part may extend from the bend to the main plate part.

As depicted, one or more openings 1622d may be formed through the front connecting part 1622c. The openings 1622a may be configured, e.g. shaped, sized and/or positioned, to avoid the first portion interfering with hooks provided on the cage and/or to increase a flexibility of the first portions 1622 in the area in which the openings are formed. As depicted, the openings 1622d may comprise openings that are substantially, square, rectangular, rhombus shaped and/or chevron shaped. Accordingly, the main plate part 1622a may be connected to the interface portion by a plurality of angled elements 1622e of the front connecting part that are angled relative to one another, e.g. in alternating directions, and relative to a principal direction in which the front connector part extends between the interface portion and the main plate part. As depicted, the angled elements may be zigzag or chevron shaped. The shapes of the angled elements 1622e may be configured to increase the flexibility of the front connecting part at the angled elements 1622e.

The first portion 1622 may further comprise a rear connecting part 1622f, for connecting the main plate part 1622a to the rear plate part 1622b. The rear connecting part 1622f may be shaped similarly to the front connecting part and may comprise square, rectangular, rhombus shaped and/or chevron shaped openings and similarly shaped angled elements which are angled relative to one another and the principal direction in which the rear connecting part 1622f extends between the main plate part and the rear plate part, e.g. to form zigzag or chevron shapes.

As depicted in FIG. 16C, the cover 1600 may be formed from a single sheet of material. For example, the cover 16400 may be a folded sheet metal component formed from a single piece of sheet metal, such as steel, aluminium, copper or alloys thereof.

It will be appreciated by those skilled in the art that although the invention has been described by way of example, with reference to one or more exemplary examples, it is not limited to the disclosed examples and that alternative examples could be constructed without departing from the scope of the invention as defined by the appended claims.

1. A cover for a cage, the cage configured to guide a signal connector towards an interface for connection with the signal connector, wherein the cover is attachable to a first surface of the cage for thermally coupling the signal connector received within the cage to a heat sink disposed outside the cage, wherein the cover comprises:
an interface portion engageable with the first surface of the cage;
an opening formed in the interface portion; and
one or more thermal coupling members resiliently connected to the interface portion and extending at least partially across the opening, wherein a first portion of one or more of the thermal coupling members is disposed on a first side of the interface portion and a second portion of one or more of the thermal coupling members is disposed on a second side of the interface portion opposite the first side.

2. The cover of claim 1, wherein the thermal coupling members comprise a corrugated plate comprising a plurality of alternating ridges and valleys that alternatingly extend through the opening between the first and second sides of the interface portion, wherein the first portion comprises the one or more ridges of the corrugated plate and the second portion comprises the one or more valleys of the corrugated plate.

3. The cover of claim 1, wherein the cover further comprises a thermal pad at least partially enclosed between the first and second portions of the thermal coupling members.

4. The cover of claim 3, wherein the thermal coupling members are resiliently deformable relative to one another in order to compress the thermal pad between the first and second portions.

5. The cover of claim 1, wherein the cover further comprises one or more side interface portions for engaging one or more side surfaces of the cage, the side interface portions arranged at angles relative to the interface portion.

6. The cover of claim 5, wherein the cover further comprises one or more side openings formed in the one or more side interface portions; and one or more side thermal coupling members resiliently connected to respective ones of the one or more side interface portions and extending at least partially across one or more of the side openings formed in the respective side interface portion, wherein a first portion of one or more of the side thermal coupling members is disposed on a first side of the respective side interface portion and a second portion of one or more of the side thermal coupling members is disposed on a second side of the respective side interface portion.

7. The cover of claim 6, wherein the cover further comprises a side thermal pad corresponding to each of the side thermal coupling members, wherein the side thermal pads are at least partially enclosed between the first and second portions of each of the side thermal coupling members.

8. The cover of claim 1, wherein the cage is a multiple slot cage configured to receive a plurality of the signal connectors side-by-side with one another within respective slots of the cage, wherein the interface portion comprises a plurality of the openings formed in the interface portion arranged to be at least partially aligned with two or more slots of the cage, wherein the cover further comprises a plurality of the thermal coupling members resiliently connected to the interface portion and extending at least partially across respective ones of the openings, wherein a first portion of the thermal coupling members is disposed on a first side of the interface portion and a second portion of the thermal coupling members is disposed on a second side of the interface portion opposite the first side.

9. A cage assembly comprising:
a cage configured to guide a signal connector towards an interface for connection with the signal connector, wherein the cage comprises a first surface;
a cover for the cage according to claim 1, wherein the interface portion of the cover is engaged with the first side of the cage.

10. The cage assembly of claim 9, wherein the cage comprises an aperture formed in the first surface, wherein the second portions of the one or more thermal coupling members extend through the aperture into an interior space of the cage.

11. The cage assembly of claim 9, wherein the assembly further comprises:
a heatsink, wherein the heatsink comprises a heatsink surface spaced apart from the first side of the cage on an opposite side of the interface portion from the cage.

12. The cage assembly of claim 11, wherein the thermal coupling members are configured such that insertion of the signal connector into the cage urges the thermal coupling members towards the heatsink surface.

13. The cage assembly of claim 11, wherein the thermal coupling members are configured such that, when the signal connector is received within the cage, the first portions of the thermal coupling member contact the heat sink surface.

14. The cage assembly of claim 11, wherein the thermal coupling members are configured such that, when the signal connector is received within the cage, the thermal coupling members are compressed between the cage and/or the signal connector, and the heatsink.

15. The cage assembly of claim 9, wherein the cage is configured to guide the signal connector along a longitudinal direction when the signal connector is inserted into the cage, and wherein the plurality of ridges and valleys of the corrugated thermal coupling member extend in a transverse direction that is perpendicular to the longitudinal direction, and
wherein the thermal coupling members comprise a corrugated plate comprising a plurality of alternating ridges and valleys that alternatingly extend through the opening between the first and second sides of the interface portion, wherein the first portion comprises the one or more ridges of the corrugated plate and the second portion comprises the one or more valleys of the corrugated plate.

16. The cage assembly of claim 9, wherein the cage further comprises a pair of opposing side surfaces arranged on either lateral side of the first surface; and one or more side apertures formed in the side surfaces, wherein the second portions of the one or more side thermal coupling members extend through the side apertures into the interior space of the cage, and
wherein the cover further comprises one or more side openings formed in the one or more side interface portions; and one or more side thermal coupling members resiliently connected to respective ones of the one or more side interface portions and extending at least partially across one or more of the side openings formed in the respective side interface portion, wherein a first portion of one or more of the side thermal coupling members is disposed on a first side of the respective side interface portion and a second portion of one or more of the side thermal coupling members is disposed on a second side of the respective side interface portion.

17. The cage assembly of claim 16, wherein the assembly further comprises: a heatsink, wherein the heatsink comprises a heatsink surface spaced apart from the first side of the cage on an opposite side of the interface portion from the cage, and wherein the assembly further comprises:
a further cage configured to guide a further signal connector towards an interface for connection with the further signal connector, wherein the further cage comprises a first surface, and wherein the further cage comprises a pair of opposing side surfaces arranged on either lateral side of the first surface; and one or more side apertures formed in the side surfaces, wherein the further cage is arranged such that one of the side surfaces of the further cage is spaced apart from one of the side surfaces of the cage; and
wherein the cover further comprises one or more side openings formed in the one or more side interface portions; and one or more side thermal coupling members resiliently connected to respective ones of the one or more side interface portions and extending at least partially across one or more of the side openings formed in the respective side interface portion, wherein a first portion of one or more of the side thermal coupling members is disposed on a first side of the respective side interface portion and a second portion of one or more of the side thermal coupling members is disposed on a second side of the respective side interface portion
wherein the interface portion of the further cover is engaged with the first side of the further cage and wherein the second portions of the one or more side thermal coupling members of the further cover extend through the side apertures of the further cover into an interior space of the further cage, wherein the heatsink comprises projecting portion projecting from the heatsink surface between the cage and the further cage, and wherein the first portions of the side thermal coupling members of the cover and further cover engage the projecting portion of the heat sink, when the signal connector and the further signal connector are installed in the cage and further cage respectively.

18. The cage assembly of claim 17, wherein the projecting portion comprises a tapered surface at a distal end of the projecting portion configured to urge the side thermal coupling members of the cage and further cage away from the projecting portion as the projecting portion is assembled between the cage and the further cage.

19. The cage assembly of claim 9, wherein the cage is a multiple slot cage configured to receive a plurality of the signal connectors side-by-side with one another within respective slots of the cage, wherein the interface portion comprises a plurality of the openings formed in the interface portion arranged to be at least partially aligned with two or more slots of the cage, wherein the cover further comprises a plurality of the thermal coupling members resiliently connected to the interface portion and extending at least partially across respective ones of the openings, wherein a first portion of the thermal coupling members is disposed on a first side of the interface portion and a second portion of the thermal coupling members is disposed on a second side of the interface portion opposite the first side; and
wherein the cage is a multiple slot cage configured to receive a plurality of the signal connectors side-by-side with one another within respective slots of the cage, wherein the first surface of the cage and the interface portion of the cover extend across each of the slots for signal connector provided in the cage.
